(19) United States
(12) Patent Application Publication
(10) Pub. No.: US 2025/0149409 A1
(43) Pub. Date: May 8, 2025

(54) SEMICONDUCTOR DEVICE

(71) Applicant: FUJI ELECTRIC CO., LTD., Kawasaki-shi (JP)

(72) Inventor: Hideo AMI, Matsumoto-city (JP)

(73) Assignee: FUJI ELECTRIC CO., LTD., Kawasaki-shi (JP)

(21) Appl. No.: 18/900,186

(22) Filed: Sep. 27, 2024

(30) Foreign Application Priority Data
Nov. 8, 2023 (JP) 2023-190937

(51) Int. Cl. H01L 23/495; H01L 23/00; H01L 25/065; H05K 5/02

(52) U.S. Cl. CPC H01L 23/49537; H01L 23/4952; H01L 23/49531; H01L 23/562; H01L 25/0655; H05K 5/0247

(57) ABSTRACT

A semiconductor device, including: a first main terminal having a first principal planar surface; a second main terminal facing the first main terminal with a gap therebetween and having a second principal planar surface located opposite to the first principal planar surface of the first main terminal; and a conductive member located in the gap and including a first outer surface adjacent and opposite to the first principal planar surface and a second outer surface adjacent and opposite to the second principal planar surface.

### CROSS-REFERENCE TO RELATED APPLICATION

This application is based upon and claims the benefit of priority of the prior Japanese Patent Application No. 2023-190937, filed on Nov. 8, 2023, the entire contents of which are incorporated herein by reference.

### BACKGROUND OF THE INVENTION

### 1. Field of the Invention

The embodiments discussed herein relate to a semiconductor device.

### 2. Background of the Related Art

A P terminal included in a semiconductor device includes a first flat plate portion and a second flat plate portion parallel to an X-Y plane and a third flat plate portion which is parallel to a Z-X plane and which connects the first flat plate portion and the second flat plate portion. A metal plate is located between the first flat plate portion and the second flat plate portion (see, for example, Japanese Laid-open Patent Publication No. 2023-070978).

### SUMMARY OF THE INVENTION

According to an aspect, there is provided a semiconductor device, including: a first main terminal including a first principal planar surface; a second main terminal facing the first main terminal with a gap therebetween and including a second principal planar surface located opposite to the first principal planar surface of the first main terminal; and a conductive member located in the gap and including a first outer surface adjacent and opposite to the first principal planar surface, and a second outer surface adjacent and opposite to the second principal planar surface.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF THE DRAWINGS

FIG. 1 is an external view of a semiconductor device according to a first embodiment;

FIG. 2 is a plan view of the semiconductor device according to the first embodiment (without a lid);

FIG. 3 is a sectional view of the semiconductor device according to the first embodiment;

FIG. 4 is a plan view of semiconductor units included in the semiconductor device according to the first embodiment;

FIG. 5 is a perspective view of lead frames included in the semiconductor device according to the first embodiment;

FIG. 6 is a plan view of a wiring unit included semiconductor device according to the first in the embodiment;

FIG. 7 is a sectional view of the wiring unit included in the semiconductor device according to the first embodiment;

FIG. 8 is a sectional view of the wiring unit included in the semiconductor device according to the first embodiment (at the time of a power supply voltage being supplied);

FIG. 9 is a sectional view of a semiconductor device taken as a reference example;

FIG. 10 is a sectional view of a semiconductor device according to a second embodiment (practical example 2-1);

FIG. 11 is a sectional view of a semiconductor device according to the second embodiment (practical example 2-2); and

FIG. 12 is a sectional view of a semiconductor device according to a third embodiment.

### DETAILED DESCRIPTION OF THE INVENTION

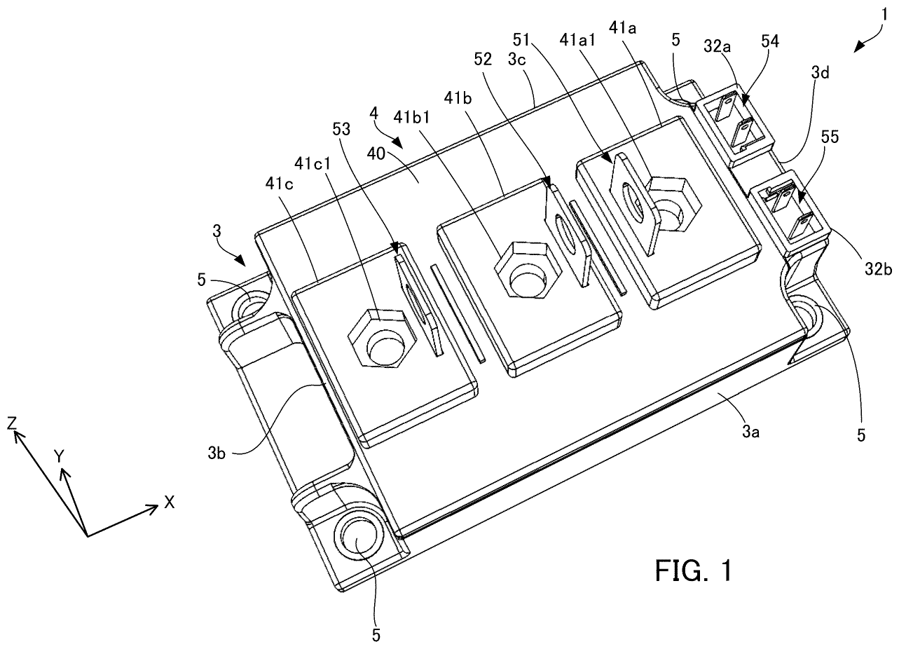

Embodiments will now be described by reference to the accompanying drawings. In the following description, a “front surface” and an “upper surface” indicate an X-Y plane which faces the upper side (+Z direction) in a semiconductor device 1 of FIG. 1. Similarly, an “upside” indicates the upward direction (+Z direction) in the semiconductor device 1 of FIG. 1. A “back surface” and a “lower surface” indicate the X-Y plane which faces the lower side (−Z direction) in the semiconductor device 1 of FIG. 1. Similarly, a “downside” indicates the downward direction (−Z direction) in the semiconductor device 1 of FIG. 1. These terms mean the same directions at need in the other drawings. “Highly placed” and “placed above” indicate an upward position (+Z direction) in the semiconductor device 1 of FIG. 1. Similarly, “placed low” and “placed below” indicate a downward position (−Z direction) in the semiconductor device 1 of FIG. 1. The “front surface,” the “upper surface,” the “upside,” the “back surface,” the “lower r surface,” the “downside,” and a “side” are simply used as expedient representation for specifying relative positional relationships and do not limit the technical idea of the present disclosure. For example, the “upside” and the “downside” do not always mean the vertical direction relative to the ground. That is to say, directions indicated by the “upside” and the “downside” are not limited to the gravity direction. Furthermore, in the following description, a “main ingredient” indicates an ingredient contained at a rate of 80 volume percent (vol %) or more. In addition, “approximately equal” means that two objects are in the range of +10%. Moreover, “perpendicular” and “rectangular,” and “parallel” means that an angle which one object forms with the other object is in the range of 90°±10° and 180°±10°, respectively.

### First Embodiment

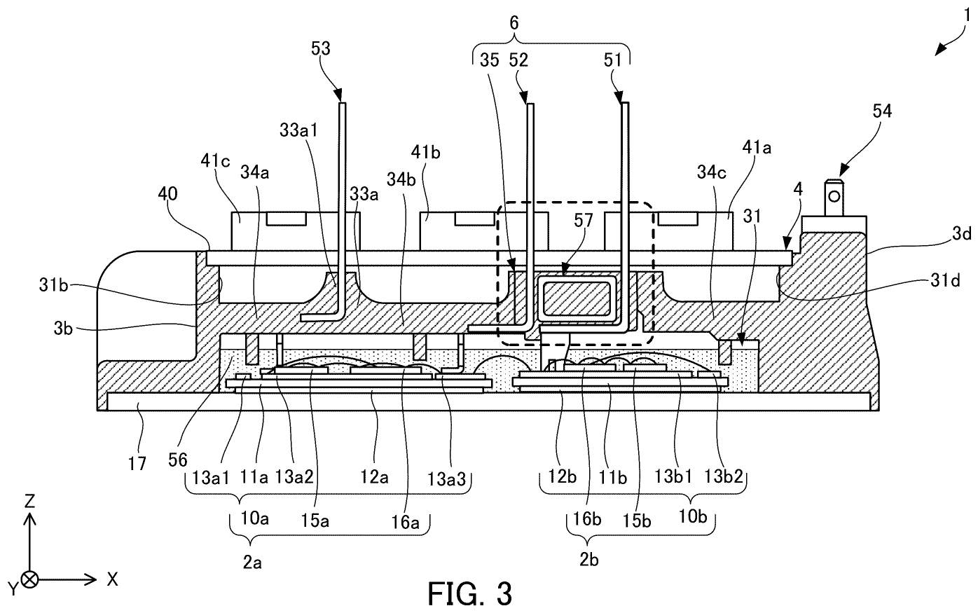

The appearance of a semiconductor device according to a first embodiment will be described by the use of FIG. 1. FIG. 1 is an external view of the semiconductor device according to the first embodiment. With a semiconductor device 1, semiconductor units 2a and 2b described later are housed in a case 3. A radiation base plate 17 which is rectangular in plan view is located on the back surface of the semiconductor device 1 (on the back side of the case 3) (see FIG. 3).

The case 3 includes sidewalls 3a through 3d and terminal openings 32a and 32b. Furthermore, the case 3 includes in plan view a fastening hole 5 in each of the four corner portions. In addition, a lid 4 is fixed on the case 3.

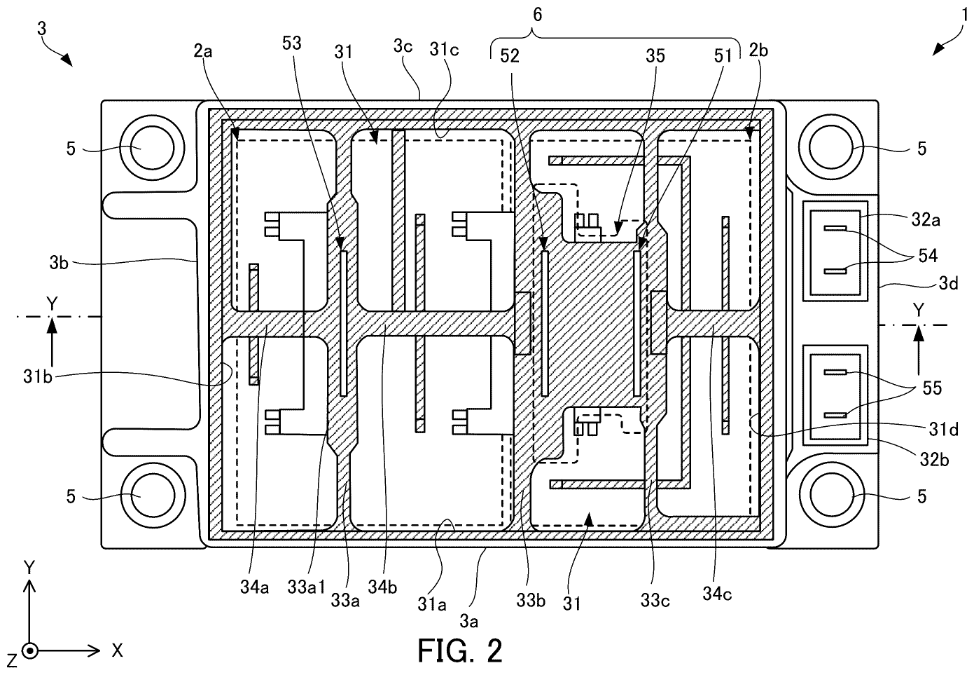

The sidewall 3b may be inverted L-shaped in a side view (see FIG. 3). The sidewalls 3a through 3d are stuck to the radiation base plate 17 with an adhesive member. The sidewalls 3a through 3d surround the semiconductor units 2a and 2b located over the radiation base plate 17 (see FIG. 2).

The terminal openings 32a and 32b are formed adjacent to and along the sidewall 3d between the fastening holes 5. Control terminals 54 and 55 protrude in the +Z direction from the terminal openings 32a and 32b respectively. The fastening holes 5 are made near the corners of a housing space 31 (see FIG. 2) enclosed by the sidewalls 3a through 3d outside the housing space 31. The semiconductor device 1 is placed on a desired area and screws inserted into the fastening holes 5 are screwed. By doing so, the semiconductor device 1 is fixed on the area.

The lid 4 includes a lid body 40 and terminal blocks 41a, 41b, and 41c formed in a longitudinal direction (in the ±X directions) on a central portion of the lid body 40. The lid body 40 has the shape of a flat plate. The lid body 40 has the shape of a rectangle corresponding to an opening enclosed by inner walls 31a through 31d (see FIG. 2).

Each of the terminal blocks 41a, 41b, and 41c is cubic. Each of the terminal blocks 41a, 41b, and 41c is integrally formed with the front surface of the lid body 40. The terminal blocks 41a, 41b, and 41c are placed so that their centers are on the dot-dash line Y-Y of FIG. 2 passing through the center of the lid body 40 and so that they are parallel to the sidewalls 3a and 3c.

Screw holes 41a1, 41b1, and 41c1 are made in the front surfaces of the terminal blocks 41a, 41b, and 41c respectively. The screw holes 41a1, 41b1, and 41c1 do not pierce the terminal blocks 41a, 41b, and 41c, respectively, or the lid body 40. Nuts are housed in the screw holes 41a1, 41b1, and 41c1.

First, second, and third lead frames 51, 52, and 53, each of which is an example of a main terminal, extend vertically upward (in the +Z direction) from the terminal blocks 41a, 41b, and 41c respectively. FIG. 1 illustrates a case where the first, second, and third lead frames 51, 52, and 53 extend vertically upward. The extending first, second, and third lead frames 51, 52, and 53 are bent toward the front surfaces of the terminal blocks 41a, 41b, and 41c respectively. Opening holes made in the first, second, and third lead frames 51, 52, and 53 bent are opposite the screw holes 41a1, 41b1, and 41c1 respectively. For example, predetermined terminals are fastened from the outside to the nuts housed in the screw holes 41a1, 41b1, and 41c1 with screws through the opening holes of the first, second, and third lead frames 51, 52, and 53 respectively. As a result, the predetermined terminals are connected mechanically and electrically to the first, second, and third lead frames 51, 52, and 53.

The inside of the case 3 of the semiconductor device 1 will now be described by the use of FIG. 2 and FIG. 3. FIG. 2 is a plan view of the semiconductor device according to the first embodiment (without the lid). FIG. 3 is a sectional view of the semiconductor device according to the first embodiment. FIG. 2 is a plan view of the semiconductor device 1 in which the lid 4 is removed and in which a sealing member 56 is not illustrated. Furthermore, the arrangement positions of the semiconductor units 2a and 2b housed in the case 3 are indicated in FIG. 2 by dashed lines. FIG. 3 is a sectional view taken along the dot-dash line Y-Y of FIG. 2.

As stated above, the case 3 includes the sidewalls 3a through 3d and the lid 4. The case 3 includes vertical beams 33a, 33b, and 33c and horizontal beams 34a, 34b, and 34c in the housing space 31 enclosed by the inner walls 31a through 31d of the sidewalls 3a through 3d. The strength of the case 3 is kept constant by the vertical beams 33a, 33b, and 33c and the horizontal beams 34a, 34b, and 34c. Furthermore, the case 3 may include beams other than the vertical beams 33a, 33b, and 33c and the horizontal beams 34a, 34b, and 34c in the housing space 31.

The inner walls 31a through 31d are formed inside the sidewalls 3a through 3d respectively and enclose the housing space 31 on all sides. The inner walls 31a and 31c correspond in plan view to long sides of the housing space 31 and the inner walls 31b and 31d correspond in plan view to short sides of the housing space 31. A level difference is formed in a circular edge of upper portions (in the +Z direction) of the inner walls 31a through 31d along the housing space 31. The lid 4 is fitted into the level difference of the inner walls 31a through 31d with an adhesive member therebetween.

The vertical beams 33a, 33b, and 33c extend in the housing space 31 in a vertical direction (in the ±Y directions) in FIG. 2. The vertical beams 33a, 33b, and 33c cross the housing space 31 and connect the inner walls 31a and 31c. At this time, the vertical beams 33a, 33b, and 33c are perpendicular to the inner walls 31a and 31c. Furthermore, the vertical beams 33a, 33b, and 33c are parallel to the inner walls 31b and 31d.

A terminal inclusion portion 33a1 is included in a central portion of the vertical beam 33a. The terminal inclusion portion 33al is formed thick (wide) in the ±X directions in the central portion of the vertical beam 33a. The back surface of the terminal inclusion portion 33a1 is flush with the back surface of the vertical beam 33a. The terminal inclusion portion 33a1 may be formed thicker in the +Z direction than the vertical beam 33a.

The terminal inclusion portion 33a1 is integrally molded with the third lead frame 53. An upper end portion of the third lead frame 53 extends vertically upward (in the +Z direction) from the front surface of the terminal inclusion portion 33al. A lower end portion of the third lead frame 53 extends vertically downward (in the −Z direction) from the back surface of the terminal inclusion portion 33a1 and is connected electrically and mechanically to the semiconductor unit 2a described later.

Furthermore, a wiring protection portion 35 is formed between the vertical beams 33b and 33c. The wiring protection portion 35 extends over an area enclosed by a dashed line indicated in FIG. 2 or FIG. 3 and is integrally connected to central portions in the ±Y directions of the vertical beams 33b and 33c. The length in the ±Y directions of the side of the wiring protection portion 35 of FIG. 2 connecting to the vertical beam 33b is greater than that in the ±Y directions of the side of the wiring protection portion 35 of FIG. 2 connecting to the vertical beam 33c. The length in the ±Y directions of the portion of the wiring protection portion 35 between the vertical beams 33b and 33c may be approximately equal to that in the ±Y directions of the first and second lead frames 51 and 52.

The wiring protection portion 35 includes the first and second lead frames 51 and 52. It is assumed that a wiring unit 6 includes the first and second lead frames 51 and 52 and the wiring protection portion 35. The details of the wiring unit 6 will be described later.

The horizontal beams 34a, 34b, and 34c are formed in line in the housing space 31 in a horizontal direction (in the ±X directions) in FIG. 2. The horizontal beams 34a, 34b, and 34c cross the housing space 31 and connect the center of the inner wall 31b and the center of the inner wall 31d. At this time, the vertical beam 33a and the wiring protection portion 35 (including the vertical beams 33b and 33c) are put between the horizontal beams 34a, 34b, and 34c. The horizontal beams 34a, 34b, and 34c are perpendicular to the inner walls 31b and 31d. Furthermore, the horizontal beams 34a, 34b, and 34c are parallel to the inner walls 31a and 31c.

The horizontal beam 34a connects the center (in the ±Y directions) of the inner wall 31b and the center (in the ±Y directions) of the vertical beam 33a. The horizontal beam 34b connects the center (in the ±Y directions) of the vertical beam 33a and the center (in the ±Y directions) of the vertical beam 33b included in the wiring protection portion 35. The horizontal beam 34c connects the center (in the ±Y directions) of the vertical beam 33c included in the wiring protection portion 35 and the center (in the ±Y directions) of the inner wall 31d. The height of the horizontal beams 34a, 34b, and 34c may be equal to that of the vertical beams 33a and 33c.

The above case 3 including the first, second, and third lead frames 51, 52, and 53 and a conductive member 57 described later may be formed by injection molding by the use of thermoplastic resin containing a filler.

Alternatively, the following method may be used. The wiring unit 6 including the first and second lead frames 51 and 52 and the wiring protection portion 35 including the conductive member 57 is formed in advance by the injection molding. Next, the case 3 including the third lead frame 53 and the wiring unit 6 is formed by the injection molding.

The thermoplastic resin is polyphenylene sulfide resin, polybutylene terephthalate resin, polyamide resin, or the like is used. The filler is glass fiber, glass beads, calcium carbide, talc, magnesium oxide, aluminum hydroxide, or the like.

The semiconductor units 2a and 2b are arranged side by side over the radiation base plate 17 in the longitudinal direction. The semiconductor units 2a and 2b are placed inside the housing space 31 of the case 3 fixed on the radiation base plate 17. The semiconductor units 2a and 2b in the housing space 31 are sealed with the sealing member 56. Insulated circuit boards, semiconductor chips, and wires included in the semiconductor units 2a and 2b and lower end portions of the first, second, and third lead frames 51, 52, and 53 need only be sealed with the sealing member 56. There is no need to seal the whole of the inside of the housing space 31. The sealing member 56 is gel or the like.

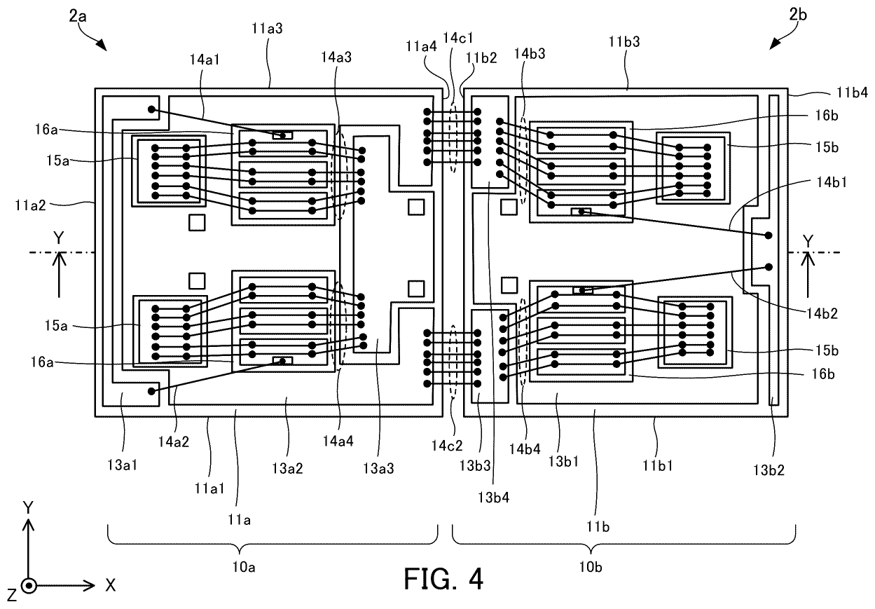

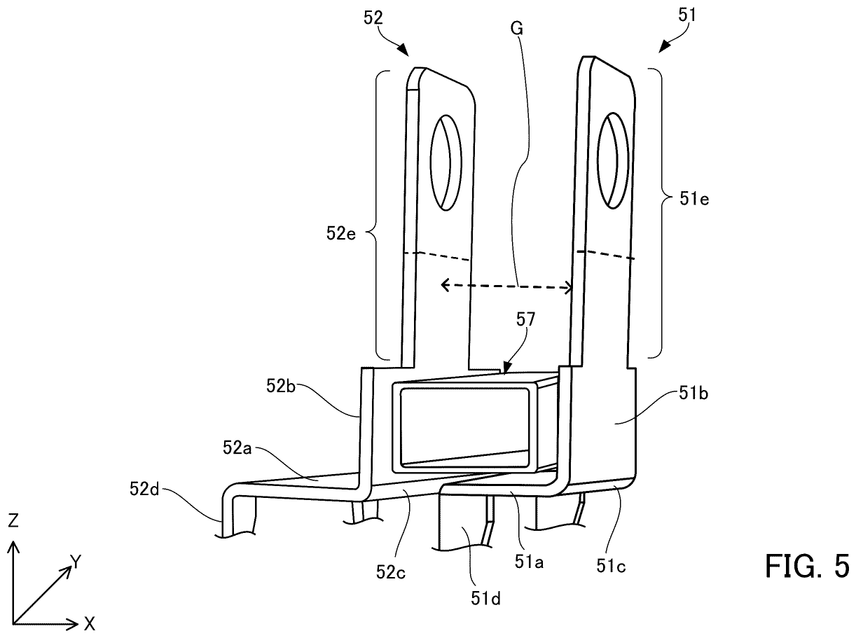

The semiconductor units 2a and 2b, the first, second, and third lead frames 51, 52, and 53, and the conductive member 57 will now be described by the use of FIG. 3, FIG. 4, and FIG. 5. FIG. 4 is a plan view of semiconductor units included in the semiconductor device according to the first embodiment. FIG. 5 is a perspective view of lead frames included in the semiconductor device according to the first embodiment. FIG. 4 illustrates the front surfaces of the semiconductor units 2a and 2b located over the radiation base plate 17. The radiation base plate 17, the first, second, and third lead frames 51, 52, and 53, and the conductive member 57 are not illustrated in FIG. 4. FIG. 5 is a perspective view of the first and second lead frames 51 and 52 and the conductive member 57.

The semiconductor units 2a and 2b include insulated circuit boards 10a and 10b and semiconductor chips 15a and 16a and 15b and 16b respectively. The first, second, and third lead frames 51, 52, and 53 are connected to these semiconductor units 2a and 2b. Each of bonding portions of the first, second, and third lead frames 51, 52, and 53 is indicated by a square in FIG. 4.

As illustrated in FIG. 4, the insulated circuit boards 10a and 10b are rectangular in plan view. As illustrated in FIG. 3 and FIG. 4, the insulated circuit board 10a includes an insulating plate 11a, a metal plate 12a formed on the back surface of the insulating plate 11a, and wiring boards 13a1 through 13a3 formed over the front surface of the insulating plate 11a. As illustrated in FIG. 3 and FIG. 4, the insulated circuit board 10b includes an insulating plate 11b, a metal plate 12b formed on the back surface of the insulating plate 11b, and wiring boards 13b1 through 13b4 formed over the front surface of the insulating plate 11b.

The wiring boards 13al through 13a3 and the metal plate 12a are smaller in external shape in plan view than the insulating plate 11a. The wiring boards 13a1 through 13a3 and the metal plate 12a are formed inside the insulating plate 11a. The wiring boards 13b1 through 13b4 and the metal plate 12b are smaller in external shape in plan view than the insulating plate 11b. The wiring boards 13b1 through 13b4 and the metal plate 12b are formed inside the insulating plate 11b. The shapes and numbers of the wiring boards 13al through 13a3 and 13b1 through 13b4 are an example.

The insulating plates 11a and 11b are rectangular in plan view. Furthermore, corner portions of the insulating plates 11a and 11b may be chamfered. For example, the corner portions of the insulating plates 11a and 11b may be R-chamfered or C-chamfered. The insulating plate 11a is surrounded on all sides by long sides 11al and 11a3 and short sides 11a2 and 11a4 corresponding to the outer peripheral portions thereof. The insulating plate 11b is surrounded on all sides by long sides 11b1 and 11b3 and short sides 11b2 and 11b4 corresponding to the outer peripheral portions thereof. The insulating plates 11a and 11b may be made of ceramics having high thermal conductivity. A main ingredient of the ceramics may be aluminum oxide, aluminum nitride, silicon nitride, or the like.

The metal plates 12a and 12b are rectangular in plan view. Furthermore, for example, corner portions of the metal plates 12a and 12b may be R-chamfered or C-chamfered. The metal plates 12a and 12b are smaller in size than the insulating plates 11a and 11b respectively. The metal plate 12a is formed on the entire back surface except an edge portion of the insulating plate 11a. The metal plate 12b is formed on the entire back surface except an edge portion of the insulating plate 11b. The metal plates 12a and 12b contain as a main ingredient metal, such as copper, aluminum, or an alloy containing at least one of them, having high thermal conductivity. In order to improve the corrosion resistance of the metal plates 12a and 12b, plating treatment may be performed on the surfaces of the metal plates 12a and 12b. At this time, nickel, a nickel-phosphorus alloy, a nickel-boron alloy, or the like is used as a plating material.

The wiring boards 13a1 through 13a3 are formed over the entire front surface except an edge portion of the insulating plate 11a. The wiring boards 13b1 through 13b4 are formed over the entire front surface except an edge portion of the insulating plate 11b. The wiring boards 13a1 through 13a3 and 13b1 through 13b4 are made of metal, such as copper, aluminum, or an alloy containing at least one of them, having good electrical conductivity. Furthermore, in order to improve corrosion resistance, plating treatment may be performed on the surfaces of the wiring boards 13a1 through 13a3 and 13b1 through 13b4. At this time, nickel, a nickel-phosphorus alloy, a nickel-boron alloy, or the like is used as a plating material. The wiring boards 13a1 through 13a3 and 13b1 through 13b4 are formed in the following way over the insulating plates 11a and 11b respectively. For example, a metal layer is formed on the front surfaces of the insulating plates 11a and 11b and treatment, such as etching, is performed on the metal layer. By doing so, the wiring boards 13al through 13a3 and 13b1 through 13b4 are obtained. Alternatively, the wiring boards 13a1 through 13a3 and 13b1 through 13b4 cut in advance out of a metal plate are pressure-bonded to the front surfaces of the insulating plates 11a and 11b respectively. By doing so, the wiring boards 13a1 through 13a3 and 13b1 through 13b4 are obtained. The wiring boards 13al through 13a3 and 13b1 through 13b4 are taken as an example. The number, shape, size, or the like of wiring boards may be properly selected at need.

The wiring board 13al has the shape of the letter “U” in plan view. The wiring board 13al is formed adjacent to the short side 11a2 of the insulating plate 11a along the short side 11a2 and extends from the long side 11a1 to the long side 11a3. The wiring board 13a2 has the shape of the letter “C” in plan view. An end portion in the −X direction of the wiring board 13a2 enters the cavity of the wiring board 13a1. An end portion in the +X direction of the wiring board 13a2 extends to the short side 11a4 and the center of the end portion in the +X direction of the wiring board 13a2 caves in toward the center of the insulating plate 11a. The width in the +Y directions of the wiring board 13a2 extends from the long side 11a1 to the long side 11a3. Two squares on the wiring board 13a2 illustrated in FIG. 4 indicate connecting portions of the lower end portion of the third lead frame 53. The wiring board 13a3 has the shape of the letter “T” in plan view. The wiring board 13a3 is formed in the cavity in the +X direction of the wiring board 13a2. Two squares on the wiring board 13a3 illustrated in FIG. 4 indicate connecting portions of the lower end portion of the second lead frame 52.

The wiring board 13b1 is approximately rectangular in plan view. The wiring board 13b1 has a convex portion in the center of an edge portion thereof facing the short side 11b2 (in the −X direction) and a concave portion in the center of an edge portion thereof facing the short side 11b4 (in the +X direction). The width in the +Y directions of the wiring board 13b1 extends from the long side 11b1 to the long side 11b3 of the insulating plate 11b. Two squares on the wiring board 13b1 illustrated in FIG. 4 indicate connecting portions of the lower end portion of the first lead frame 51.

The wiring board 13b2 has a straight shape in plan view. The wiring board 13b2 is formed adjacent to the short side 11b4 of the insulating plate 11b along the short side 11b4. A central portion of the wiring board 13b2 includes a convex portion projecting toward the short side 11b2. This convex portion enters the concave portion of the wiring board 13b1. The wiring boards 13b3 and 13b4 are rectangular in plan view. The wiring boards 13b3 and 13b4 are formed adjacent to the short side 11b2 of the insulating plate 11b along the short side 11b2 and have the convex portion of the wiring board 13b1 therebetween.

The insulated circuit boards 10a and 10b each having the above structure may be direct copper bonding (DCB) substrates, active metal brazed (AMB) substrates, or the like. Heat generated by the semiconductor chips 15a and 16a and 15b and 16b described later is conducted to the radiation base plate 17 via the wiring boards 13a2 and 13b1, the insulating plates 11a and 11b, and the metal plates 12a and 12b respectively and is dissipated from the back surface of the radiation base plate 17. The insulated circuit boards 10a and 10b are bonded to the front surface of the radiation base plate 17 with a bonding member (not illustrated) therebetween. The bonding member is solder or the like. Pb-free solder is used as the solder. The Pb-free solder contains as a main ingredient at least one of, for example, a tin-silver-copper alloy, a tin-zinc-bismuth alloy, a tin-copper alloy, and a tin-silver-indium-bismuth alloy. Furthermore, the solder may contain an additive such as nickel, germanium, cobalt, antimony, or silicon. The solder containing an additive improves wettability, a gloss, and bonding strength and reliability is improved.

The semiconductor chips 15a, 16a, 15b, and 16b may contain as a main ingredient silicon. However, their main ingredients are not limited to silicon. The semiconductor chips 15a, 16a, 15b, and 16b may contain as a main ingredient a wide-band-gap semiconductor. The wide-band-gap semiconductor is silicon carbide, gallium nitride, or the like. Each of the semiconductor chips 15a and 15b includes a diode element. For example, a Schottky barrier diode (SBD) or a P-intrinsic-N (PiN) diode may be used as a free wheeling diode (FWD). Each of the semiconductor chips 15a and 15b has on the back surface a cathode electrode as a low potential side electrode (output side) and has on the front surface an anode electrode as a high potential side electrode (input side).

Each of the semiconductor chips 16a and 16b (second and first semiconductor chips) includes a switching element. The switching element is an insulated gate bipolar transistor (IGBT), a power metal oxide semiconductor field effect transistor (MOSFET), or the like. If each of the semiconductor chips 16a and 16b is an IGBT, then it has on the back surface a collector electrode as a high potential side electrode (input side) (second and first high potential side electrodes) and has on the front surface a gate electrode and an emitter electrode as a control electrode and a low potential side electrode (output side) (second and first low potential side electrodes) respectively. If each of the semiconductor chips 16a and 16b is a power MOSFET, then it has on the back surface a drain electrode as a high potential side electrode (input side) and has on the front surface a gate electrode and a source electrode as a control electrode and a low potential side electrode (output side) respectively.

The back surfaces of the semiconductor chips 15a and 16a and 15b and 16b are bonded to the wiring boards 13a2 and 13b1, respectively, with a bonding member (not illustrated) therebetween. For example, the bonding member may be the above solder. Alternatively, a sintered metal body may be used as the bonding member in place of the solder.

Furthermore, a reverse conducting (RC)-IGBT having both of the function of an IGBT and the function of an FWD may be used as each of the semiconductor chips 16a and 16b. In this case, the semiconductor chips 15a and 15b are excluded.

Alternatively, each of the switching elements included in the semiconductor chips 16a and 16b may be a power MOSFET containing as a main ingredient silicon carbide. With the power MOSFET, a body diode may function as an FWD. For example, each of the semiconductor chips 16a and 16b has on the back surface a drain electrode as a high potential side electrode (input side) and has on the front surface a gate electrode and a source electrode as a control electrode and a low potential side electrode (output side) respectively. In this case, the semiconductor chips 15a and 15b are excluded.

Wires 14a1 through 14a4, 14b1 through 14b4, 14c1, and 14c2 are made of a material, such as gold, silver, copper, aluminum, or an alloy containing at least one of them, having good electrical conductivity. The diameter of the wires 14a1, 14a2, 14b1, and 14b2 may be smaller than that of the wires 14a3, 14a4, 14b3, 14b4, 14c1, and 14c2.

The wires 14a1 and 14a2 connect the wiring board 13a1 and the control electrodes of the semiconductor chips 16a mechanically and electrically. The wires 14a3 and 14a4 mechanically and electrically connect the wiring board 13a3, the low potential side electrodes on the front surfaces of the semiconductor chips 16a, and the high potential side electrodes on the front surfaces of the semiconductor chips 15a.

The wires 14b1 and 14b2 connect the wiring board 13b2 and the control electrodes of the semiconductor chips 16b mechanically and electrically. The wires 14b3 mechanically and electrically connect the wiring board 13b4, the low potential side electrodes on the front surface of the semiconductor chip 16b, and the high potential side electrodes on the front surface of the semiconductor chip 15b. The wires 14b4 mechanically and electrically connect the wiring board 13b3, the low potential side electrodes on the front surface of the semiconductor chip 16b, and the high potential side electrodes on the front surface of the semiconductor chip 15b. The wires 14c1 mechanically and electrically connect the wiring board 13a2 and the wiring board 13b4. The wires 14c2 mechanically and electrically connect the wiring board 13a2 and the wiring board 13b3.

Accordingly, with the semiconductor units 2a and 2b illustrated in FIG. 4, the low potential side electrodes on the front surfaces of the semiconductor chips 16b are electrically connected to the high potential side electrodes on the back surfaces of the semiconductor chips 16a via the wires 14b3 and 14b4, the wiring boards 13b4 and 13b3, the wires 14c1 and 14c2, and the wiring board 13a2.

Furthermore, the low potential side electrodes on the front surfaces of the semiconductor chips 16a are electrically connected to the wiring board 13a3 via the wires 14a3 and 14a4. In addition, the low potential side electrodes on the front surfaces of the semiconductor chips 16b are electrically connected to the wiring board 13a2 via the wires 14b3 and 14b4, the wiring boards 13b4 and 13b3, and the wires 14c1 and 14c2. The high potential side electrodes on the back surfaces of the semiconductor chips 16a are electrically connected to the wiring board 13a2.

In the first embodiment, terminals are connected from the outside to the first, second, and third lead frames 51, 52, and 53 (first, second, and third main terminals), each of which is an example of a main terminal. The first, second, and third lead frames 51, 52, and 53 are made of a material, such as gold, silver, copper, aluminum, or an alloy containing at least one of them, having good electrical conductivity. Furthermore, in order to improve corrosion resistance, plating treatment may be performed on the surfaces of the first, second, and third lead frames 51, 52, and 53. At this time, nickel, a nickel-phosphorus alloy, a nickel-boron alloy, or the like is used as a plating material.

The first lead frame 51 is electrically connected to the high potential side electrodes on the back surfaces of the semiconductor chips 16b via the wiring board 13b1. A first power supply voltage is supplied to the first lead frame 51.

The second lead frame 52 is electrically connected to the low potential side electrodes on the front surfaces of the semiconductor chips 16a via the wiring board 13a3 and the wires 14a3 and 14a4. A second power supply voltage lower than the first power supply voltage is supplied to the second lead frame 52. For example, the first power supply voltage may be positive and the second power supply voltage may be negative.

The third lead frame 53 is electrically connected to the low potential side electrodes on the front surfaces of the semiconductor chips 16b via the wiring board 13a2, the wires 14c1 and 14c2, the wiring boards 13b4 and 13b3, and the wires 14b3 and 14b4. Furthermore, the third lead frame 53 is electrically connected to the high potential side electrodes on the back surfaces of the semiconductor chips 16a via the wiring board 13a2. An output voltage may be applied to the third lead frame 53.

As illustrated in FIG. 5, the first lead frame 51 includes a first horizontal portion 51a, a first vertical portion 51b, and a first leg portion 51d. Furthermore, the first horizontal portion 51a and the first vertical portion 51b bend at a first bent portion 51c so as to form the shape of letter “L”. To be concrete, one end of the first horizontal portion 51a and one end of the first vertical portion 51b are connected at the first bent portion 51c. The first horizontal portion 51a extends parallel to the principal planar surface (X-Y plane) of the insulated circuit board 10b and extends in a direction (in the +X direction) in which the first horizontal portion 51a becomes more distant from a second bent portion 52c of the second lead frame 52 to the first bent portion 51c. The first horizontal portion 51a may be situated at a predetermined height in a height direction (in the +Z direction) between the insulated circuit board 10b and the lid 4 of the case 3. In addition, the first horizontal portion 51a may be flush with a second horizontal portion 52a described later.

The first vertical portion 51b extends upward from the first bent portion 51c perpendicularly to the principal planar surface (X-Y plane) of the insulated circuit board 10b (in the +Z direction). That is to say, the principal planar surface of the first vertical portion 51b is parallel to the principal planar surface of a second vertical portion 52b described later and there is a predetermined gap G between them. The distance of the gap G may be set according to voltages supplied to the first lead frame 51 and the second lead frame 52.

Furthermore, the width (length in the +Y directions) of the first vertical portion 51b may be approximately equal to the width (length in the +Y directions) of the second vertical portion 52b. The width (length in the +Y directions) of the second vertical portion 52b may be different from the width (length in the +Y directions) of the first vertical portion 51b at need.

As stated above, one end portion of the first lead frame 51 is connected mechanically and electrically to the wiring board 13b1 and the other end portion of the first lead frame 51 extends from the lid 4 of the case 3 (terminal block 41a) to the outside. The first vertical portion 51b includes a first external connection portion 51e at the other end portion of the first lead frame 51. The first external connection portion 51e extends upward (in the +Z direction) further from the first vertical portion 51b with respect to the insulated circuit board 10b and extends from the lid 4 of the case 3 (terminal block 41a) to the outside. FIG. 5 illustrates a case where the first external connection portion 51e extends upward. For example, a portion over a dashed line of the first external connection portion 51e extends vertically upward from the lid 4 (terminal block 41a). The portion of the first external connection portion 51e extending vertically upward from the lid 4 (terminal block 41a) is bent to the side opposite to the terminal block 41b. That is to say, the bent portion of the first external connection portion 51e is parallel to the upper surface of the lid 4 (terminal block 41a) and may extend in a direction (in the +X direction) opposite to the second lead frame 52. The first horizontal portion 51a, the first vertical portion 51b, and the first external connection portion 51e of the first lead frame 51 have the shape of a flat plate.

The first leg portion 51d extends downward (in the −Z direction) from the other end of the first horizontal portion 51a and includes the one end portion of the first lead frame 51 connected mechanically and electrically to the wiring board 13b1. The one end portion of the first lead frame 51 may be bonded to the wiring board 13b1 with the above bonding member. Alternatively, the one end portion of the first lead frame 51 may be bonded to the wiring board 13b1 by ultrasonic bonding.

As illustrated in FIG. 5, the second lead frame 52 includes a second horizontal portion 52a, a second vertical portion 52b, and a second leg portion 52d. Furthermore, the second horizontal portion 52a and the second vertical portion 52b bend at a second bent portion 52c so as to form the shape of letter “L”. To be concrete, one end of the second horizontal portion 52a and one end of the second vertical portion 52b are connected at the second bent portion 52c. The second horizontal portion 52a extends from the second bent portion 52c parallel to the principal planar surface (X-Y plane) of the insulated circuit board 10a in a direction (in the −X direction) opposite to the first lead frame 51. The second horizontal portion 52a may be situated at a predetermined height in the height direction (in the +Z direction) between the insulated circuit board 10a and the lid 4 of the case 3. In addition, the second horizontal portion 52a may be flush with the first horizontal portion 51a.

The second vertical portion 52b extends upward from the second bent portion 52c perpendicularly to the principal planar surface (X-Y plane) of the insulated circuit board 10a (in the +Z direction). As stated above, one end portion of the second lead frame 52 is connected mechanically and electrically to the wiring board 13a3 and the other end portion of the second lead frame 52 extends from the lid 4 of the case 3 (terminal block 41b) to the outside. The second vertical portion 52b includes a second external connection portion 52e at the other end portion of the second lead frame 52. The second external connection portion 52e extends upward (in the +Z direction) further from the second vertical portion 52b with respect to the insulated circuit board 10a and extends from the lid 4 of the case 3 (terminal block 41b) to the outside. FIG. 5 illustrates a case where the second external connection portion 52e extends upward. For example, a portion over a dashed line of the second external connection portion 52e extends vertically upward from the lid 4 (terminal block 41b). The portion of the second external connection portion 52e extending vertically upward from the lid 4 (terminal block 41b) is bent to the side opposite to the terminal block 41a. That is to say, the bent portion of the second external connection portion 52e is parallel to the upper surface of the lid 4 (terminal block 41b) and may extend in a direction (in the −X direction) opposite to the first lead frame 51. The second horizontal portion 52a and the second vertical portion 52b including the second external connection portion 52e of the second lead frame 52 may have the shape of a flat plate.

The second leg portion 52d extends downward (in the −Z direction) from the other end of the second horizontal portion 52a and includes the one end portion of the second lead frame 52 connected mechanically and electrically to the wiring board 13a3. The one end portion of the second lead frame 52 may be bonded to the wiring board 13a3 with the above bonding member. Alternatively, the one end portion of the second lead frame 52 may be bonded to the wiring board 13a3 by ultrasonic bonding.

The third lead frame 53 may have the same structure as the second lead frame 52 has. With the third lead frame 53, a third horizontal portion and a third vertical portion also bend at a third bent portion (reference numerals are omitted) so as to form the shape of letter “L”. Furthermore, the third lead frame 53 includes a third leg portion and a third external connection portion (reference numerals are omitted).

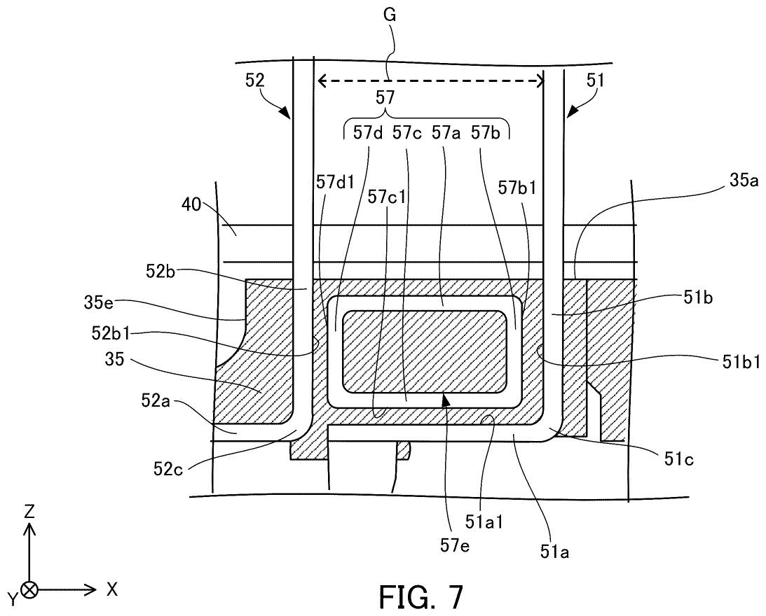

In addition, the conductive member 57 is located in the gap G between the first lead frame 51 and the second lead frame 52. The conductive member 57 need only meet the following condition. The conductive member 57 does not touch the first lead frame 51 or the second lead frame 52 and is not electrically connected to the first lead frame 51 or the second lead frame 52. An insulating material (such as the above thermoplastic resin) is located in the gap G. Accordingly, positional relationships between the conductive member 57, the first lead frame 51, and the second lead frame 52 may be maintained. Furthermore, positional relationships between the conductive member 57, the first lead frame 51, and the second lead frame 52 may be maintained by leaving spaces between them. A predetermined space is left in this way between the conductive member 57 and the first lead frame 51 and between the conductive member 57 and the second lead frame 52. The conductive member 57 may be made of the same material that is used for forming the first, second, and third lead frames 51, 52, and 53. Furthermore, plating treatment may be performed on the surface of the conductive member 57 in the same way as with the first, second, and third lead frames 51, 52, and 53. The conductive member 57 has the shape of a tube. A penetration hole 57e (see FIG. 7) is surrounded on all sides by four outer surfaces in order. The conductive member 57 is located so that a penetration direction of the penetration hole 57e will be the +Y directions. The details of the conductive member 57 will be described later.

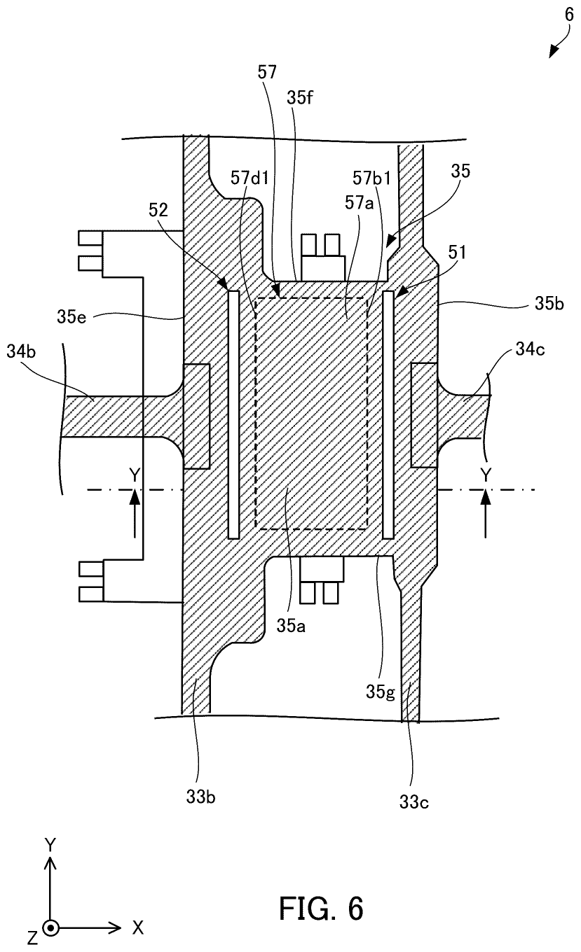

The wiring unit 6 including the first and second lead frames 51 and 52 will now be described by the use of FIG. 6 and FIG. 7. FIG. 6 is a plan view of the wiring unit included in the semiconductor device according to the first embodiment. FIG. 7 is a sectional view of the wiring unit included in the semiconductor device according to the first embodiment. FIG. 6 is an enlarged fragmentary plan view of the wiring unit 6 illustrated in FIG. 3. Furthermore, the arrangement position of the conductive member 57 is indicated by a dashed line in FIG. 6. FIG. 7 is a fragmentary sectional view taken along the dot-dash line Y-Y of FIG. 6.

The wiring unit 6 includes the first and second lead frames 51 and 52, the conductive member 57, and the wiring protection portion 35 including the whole of the conductive member 57, part of the first lead frames 51, and part of the second lead frames 52.

The wiring protection portion 35 includes at least an inclusion surface 35a, a front surface 35b, a back surface 35e, and sides 35f and 35g. The inclusion surface 35a corresponds to the upper surface of the wiring protection portion 35. The inclusion surface 35a is approximately plane. The first and second lead frames 51 and 52 extend vertically upward from the inclusion surface 35a.

The front surface 35b corresponds to an end surface in the +X direction of the wiring protection portion 35. The front surface 35b may be parallel to the first vertical portion 51b of the first lead frame 51. The vertical beam 33c is integrally bonded to the front surface 35b. Furthermore, the horizontal beam 34c is integrally bonded to the center of the front surface 35b.

The back surface 35e corresponds to an end surface in the −X direction of the wiring protection portion 35. The back surface 35e may be parallel to the second vertical portion 52b of the second lead frame 52. The vertical beam 33b is integrally bonded to the back surface 35e. Furthermore, the horizontal beam 34b is integrally bonded to the center of the back surface 35e. The sides 35f and 35g correspond to end surfaces in the +Y direction of the wiring protection portion 35 and may be parallel to each other.

The first vertical portion 51b of the first lead frame 51 and the second vertical portion 52b of the second lead frame 52 are located with the gap G therebetween. At this time, the first horizontal portion 51a of the first lead frame 51 does not touch the second lead frame 52 and is away from the second lead frame 52. The first vertical portion 51b of the first lead frame 51 and the second vertical portion 52b of the second lead frame 52 need only include portions opposite each other. Furthermore, the portions of the first vertical portion 51b of the first lead frame 51 and the second vertical portion 52b of the second lead frame 52 may be opposite with the gap G therebetween.

As stated above, the conductive member 57 has the shape of a tube surrounded by the four outer surfaces. The conductive member 57 includes an upper portion 57a, a side portion 57b, a lower portion 57c, and a side portion 57d by which the penetration hole 57e is surrounded in order on all sides. A penetration direction of the penetration hole 57e is the +Y directions. The width in the +Y directions of the upper portion 57a, the side portion 57b, the lower portion 57c, and the side portion 57d is approximately equal. Furthermore, this width is approximately equal to the width in the +Y directions of the first lead frame 51 and the second lead frame 52. If the first lead frame 51 and the second lead frame 52 differ in width in the +Y directions, then the width in the +Y directions of the upper portion 57a, the side portion 57b, the lower portion 57c, and the side portion 57d may be equal to the width in the +Y directions of one of the first lead frame 51 and the second lead frame 52 having greater width in the +Y directions than the other.

The length in the +X directions of the upper portion 57a and the lower portion 57c is approximately equal. The upper portion 57a and the lower portion 57c are parallel to each other and are opposite each other. The length in the #X directions of the upper portion 57a and the lower portion 57c may change according to the distance of the gap G between the first lead frame 51 and the second lead frame 52. The length (height) in the +Z directions of the side portions 57b and 57d is approximately equal. The side portions 57b and 57d are parallel to each other and are opposite each other. The length (height) in the +Z directions of the side portions 57b and 57d may change according to the height from the first horizontal portion 51a of the first lead frame 51 to the lid body 40. The length (height) in the +Z directions of the side portions 57b and 57d need only fall within a range in which when the conductive member 57 is located in the gap G, the upper portion 57a of the conductive member 57 does not touch the lid body 40.

The side portions 57b and 57d are connected to the upper portion 57a and the lower portion 57c perpendicularly thereto. Furthermore, in this case, the length in the +X directions of the upper portion 57a and the lower portion 57c is greater than the length (height) in the +Z directions of the side portions 57b and 57d. Each of connecting portions of the upper portion 57a, the side portion 57b, the lower portion 57c, and the side portion 57d may be R-chamfered or form a right angle.

In addition, the side portion 57b, the lower portion 57c, and the side portion 57d include outer surfaces 57b1, 57c1, and 57d1 (first, third, and second outer surfaces), respectively, which face the outside. With the conductive member 57, the outer surface 57b1 of the side portion 57b is adjacent and opposite to a first principal planar surface 51b1 of the first vertical portion 51b of the first lead frame 51. The outer surface 57c1 of the lower portion 57c is adjacent and opposite to a third principal planar surface 51a1 of the first horizontal portion 51a of the first lead frame 51. The outer surface 57d1 of the side portion 57d is adjacent and opposite to a second principal planar surface 52b1 of the second vertical portion 52b of the second lead frame 52. In this case, being adjacent means distance at which a current is induced in the conductive member 57 due to currents flowing through the first lead frame 51 and the second lead frame 52. In this case, for example, the distance may be longer than or equal to 0.5 mm and shorter than or equal to 4 mm.

Furthermore, the conductive member 57 is also sealed in the gap G between the first lead frame 51 and the second lead frame 52 with the wiring protection portion 35. That is to say, the whole of the penetration hole 57e of the conductive member 57 and the whole of the surface of the conductive member 57 are sealed. To be more concrete, the wiring protection portion 35 completely covers the upper portion 57a of the conductive member 57 and all of a space between the outer surface 57b1 of the conductive member 57 and the first principal planar surface 51b1 of the first lead frame 51, a space between the outer surface 57c1 of the conductive member 57 and the third principal planar surface 51a1 of the first lead frame 51, and a space between the outer surface 57d1 of the conductive member 57 and the second principal planar surface 52b1 of the second lead frame 52 are sealed. As a result, insulation between the conductive member 57 and the first and second lead frames 51 and 52 is maintained. In addition, the potential of the conductive member 57 is in a floating state.

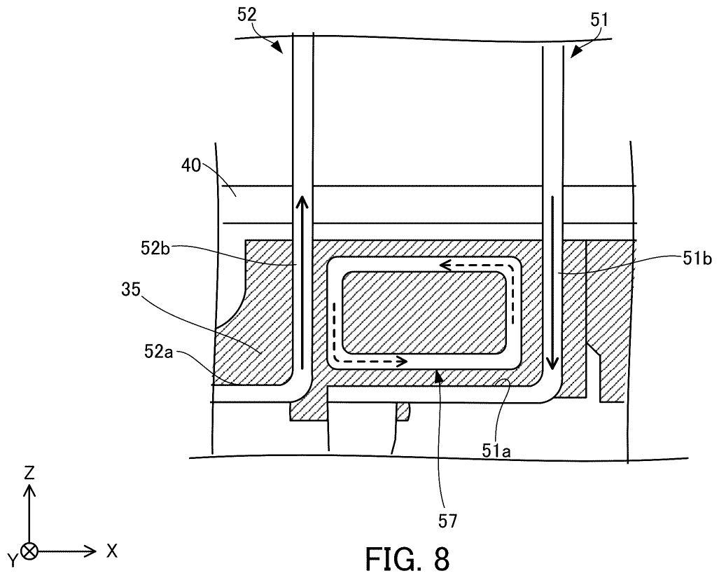

The supply of a power supply voltage to the first and second lead frames 51 and 52 of the semiconductor device 1 will now be described by the use of FIG. 7 and FIG. 8. FIG. 8 is a sectional view of the wiring unit included in the semiconductor device according to the first embodiment (at the time of a power supply voltage being supplied). FIG. 8 corresponds to FIG. 7. A downward arrow in the first lead frame 51 illustrated in FIG. 8 indicates a direction in which a current flows by a power supply voltage supplied. An upward arrow in the second lead frame 52 illustrated in FIG. 8 indicates a direction in which a current flows by a power supply voltage supplied. Furthermore, a dashed arrow in the conductive member 57 illustrated in FIG. 8 indicates the flow of a current induced by the currents flowing through the first and second lead frames 51 and 52.

As stated above, with the semiconductor device 1, the first power supply voltage and the second power supply voltage lower than the first power supply voltage are supplied to the first and second lead frames 51 and 52 respectively. When the first power supply voltage is supplied to the first lead frame 51, a current flows through the first lead frame 51 in the −Z direction. At this time, a current flowing in a direction (in the +Z direction) opposite to the −Z direction is induced in the side portion 57b of the conductive member 57 including the outer surface 57b1 which is adjacent and opposite to the first vertical portion 51b of the first lead frame 51. In addition, similarly, a current flowing in a direction (in the +X direction) opposite to the −X direction is induced in the lower portion 57c of the conductive member 57 including the outer surface 57c1 which is adjacent and opposite to the first horizontal portion 51a of the first lead frame 51. As a result, a magnetic field generated due to a current flowing through the side portion 57b and the lower portion 57c of the conductive member 57 and a magnetic field generated due to a current flowing through the first vertical portion 51b and the first horizontal portion 51a of the first lead frame 51 cancel. This reduces influence caused by parasitic inductance. The influence is an increase in surge voltage, oscillation, the generation of noise, or the like.

A current induced in the conductive member 57 flows counterclockwise through the side portion 57b, the upper portion 57a, the side portion 57d, and the lower portion 57c. The current induced in the conductive member 57 flows through the side portion 57d in the −Z direction. On the other hand, when the second power supply voltage lower than the first power supply voltage is supplied to the second lead frame 52, a current flows through the second lead frame 52 in the +Z direction. The direction in which the current flows through the second lead frame 52 adjacent and opposite to the side portion 57d of the conductive member 57 is opposite to the direction in which the current flows through the side portion 57d of the conductive member 57. Accordingly, the current flows through the side portion 57d of the conductive member 57 and the current flows through the second lead frame 52 accelerate each other.

Furthermore, a case where the second power supply voltage is supplied to the second lead frame 52 is the same as the case where the first power supply voltage is supplied to the first lead frame 51. That is to say, a current flowing in a direction (in the −X direction) opposite to the +X direction is induced in the side portion 57d of the conductive member 57 including the outer surface 57d1 which is adjacent and opposite to the second vertical portion 52b of the second lead frame 52. As a result, a magnetic field generated due to the current flowing through the side portion 57d of the conductive member 57 and a magnetic field generated due to the current flowing through the second lead frame 52 cancel. Accordingly, the influence of parasitic inductance is reduced. In addition, the current flowing through the side portion 57b of the conductive member 57 and the current flowing through the first lead frame 51 accelerate each other. The potential of the conductive member 57 is in a floating state and a voltage is not directly applied from the outside. Accordingly, the current indicated by the dashed arrow is induced in the conductive member 57 and the influence of parasitic inductance is reduced.

In addition, the conductive member 57 is located in the gap G between the first lead frame 51 and the second lead frame 52. As a result, a capacitance component is added. The addition of the capacitance component also reduces the influence of parasitic inductance.

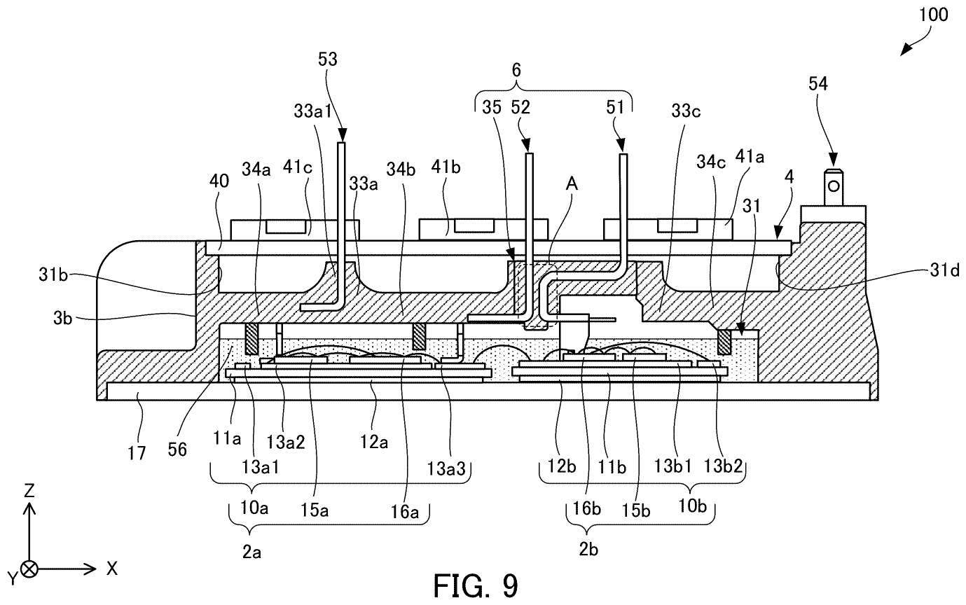

A the semiconductor device not including the conductive member 57 will now be described as a reference example by the use of FIG. 9. FIG. 9 is a sectional view of a semiconductor device taken as a reference example. FIG. 9 corresponds to FIG. 3 in the first embodiment. Components of a semiconductor device 100 taken as a reference example which are the same as those of the semiconductor device 1 according to the first embodiment are marked with the same reference numerals.

Unlike the semiconductor device 1, the semiconductor device 100 does not include the conductive member 57. Furthermore, a first lead frame 51 included in the semiconductor device 100 differs in shape from the first lead frame 51 included in the semiconductor device 1. With the semiconductor device 100, part of the first lead frame 51 is adjacent to a second lead frame 52 in an area A illustrated in FIG. 9. First and second power supply voltages are supplied to the first and second lead frames 51 and 52 and currents flow through the first and second lead frames 51 and 52 in opposite directions. In this case, the part of the first lead frame 51 is adjacent to the second lead frame 52. Accordingly, a magnetic field generated due to the current flowing through the first lead frame 51 and a magnetic field generated due to the current flowing through the second lead frame 52 cancel. As a result, the influence of parasitic inductance is reduced.

With the semiconductor device 100, however, there is need to make the part of the first lead frame 51 adjacent to the second lead frame 52 in order to reduce the influence of parasitic inductance. That is to say, with the semiconductor device 100, restrictions are imposed on the shape, the arrangement, and the wiring, such as wiring routing, of the first and second lead frames 51 and 52. This decreases flexibility in designing the semiconductor device 100.

On the other hand, the above semiconductor device 1 includes the first lead frame 51 including the first principal planar surface 51b1 (and the third principal planar surface 51a1), the second lead frame 52 facing the first lead frame 51 with the gap G therebetween and including the second principal planar surface 52b1 located opposite the first principal planar surface 51b1 of the first lead frame 51, and the conductive member 57 located in the gap G and including the outer surface 57b1 (and the outer surface 57c1) adjacent and opposite to the first principal planar surface 51b1 (and the third principal planar surface 51a1) and the outer surface 57d1 adjacent and opposite to the second principal planar surface 52b1. As a result, a current flowing in the opposite direction is induced in the side portion 57b (and the lower portion 57c) of the conductive member 57 adjacent and opposite to the first lead frame 51 with respect to a current flowing through the first lead frame 51. Accordingly, a magnetic field generated due to the current flowing through the side portion 57b (and the lower portion 57c) of the conductive member 57 and a magnetic field generated due to the current flowing through the first lead frame 51 cancel and the influence of parasitic inductance is reduced. Similarly, a magnetic field generated due to a current flowing through the side portion 57d of the conductive member 57 and a magnetic field generated due to a current flowing through the second lead frame 52 cancel and the influence of parasitic inductance is reduced. That is to say, with the semiconductor device 1, the conductive member 57 is located between the first lead frame 51 and the second lead frame 52 in order to reduce the influence of parasitic inductance. This relaxes restrictions on the shape, the arrangement, and wiring routing of the first lead frame 51 and the second lead frame 52 and flexibility in design regarding the first lead frame 51 and the second lead frame 52 is improved. As a result, flexibility in designing the semiconductor device 1 is also improved.

### Second Embodiment

In a second embodiment, practical examples in which the conductive member 57 is located between the first lead frame 51 and the second lead frame 52 in the semiconductor device 1 according to the first embodiment arranged or shaped in various ways will be described. Refer to FIG. 7 for reference numerals corresponding to components of a conductive member 57 in the second embodiment.

### Practical Example 2-1

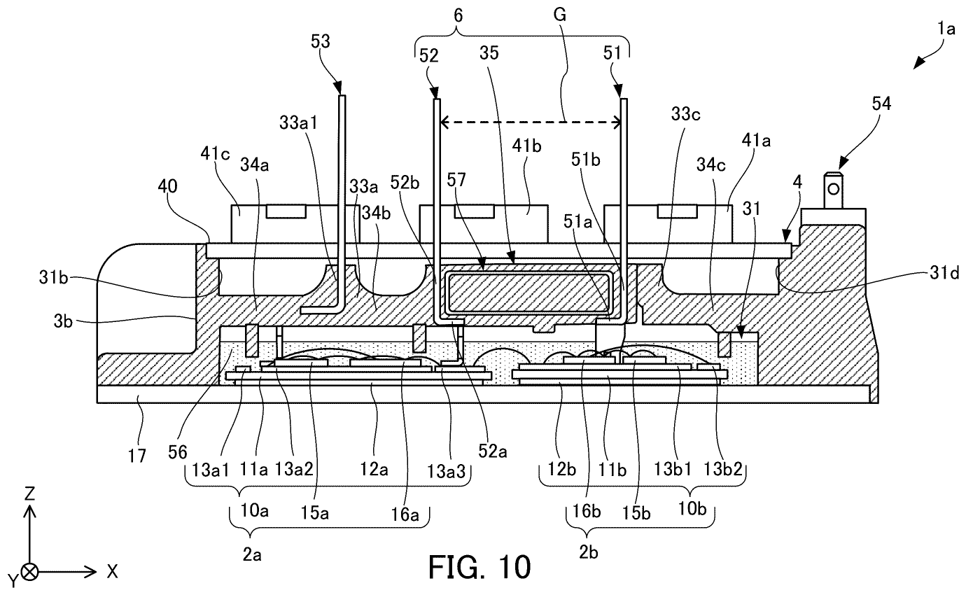

A semiconductor device in practical example 2-1 will be described by the use of FIG. 10. FIG. 10 is a sectional view of a semiconductor device according to the second embodiment (practical example 2-1). FIG. 10 is a sectional view taken along the same line as with FIG. 3 in the first embodiment.

The structure of a semiconductor device 1a in practical example 2-1 is the same as that of the semiconductor device 1 according to the first embodiment except first and second lead frames 51 and 52 and a conductive member 57. With the first and second lead frames 51 and 52 in practical example 2-1, first and second horizontal portions 51a and 52a are shorter in the ±X directions than the first and second horizontal portions 51a and 52a of the first and second lead frames 51 and 52, respectively, in the first embodiment.

Furthermore, with the semiconductor device 1a, the second lead frame 52 faces a direction opposite to the second lead frame 52 of the semiconductor device 1 with respect to the ±X directions. As a result, with the semiconductor device 1a, the distance of a gap G between the first and second lead frames 51 and 52 is longer than the gap G in the semiconductor device 1. Accordingly, the length of an upper portion 57a and a lower portion 57c of the conductive member 57 in the semiconductor device 1a is greater than that of the upper portion 57a and the lower portion 57c of the conductive member 57 in the semiconductor device 1.

As illustrated in FIG. 10, even if the first and second lead frames 51 and 52 are arranged and shaped in this way in the semiconductor device 1a, the conductive member 57 corresponding in size to the gap G between the first and second lead frames 51 and 52 is located in the gap G. In this case, an outer surface 57b1 of a side portion 57b and an outer surface 57c1 of the lower portion 57c of the conductive member 57 are adjacent and opposite to a first principal planar surface 51b1 of a first vertical portion 51b and a third principal planar surface 51a1 of the first horizontal portion 51a, respectively, of the first lead frame 51. Furthermore, an outer surface 57d1 of a side portion 57d and the outer surface 57c1 of the lower portion 57c of the conductive member 57 are adjacent and opposite to a principal planar surface (reference numeral is omitted) opposite to a second principal planar surface 52b1 of a second vertical portion 52b and a principal planar surface (reference numeral is omitted) of a second horizontal portion 52a, respectively, of the second lead frame 52.

Accordingly, with the semiconductor device 1a in practical example 2-1, the influence of parasitic inductance is reduced, restrictions on the shape, the arrangement, and wiring routing of the first lead frame 51 and the second lead frame 52 are relaxed, and flexibility in design regarding the first lead frame 51 and the second lead frame 52 is improved. This is the same with the first embodiment.

### Practical Example 2-2

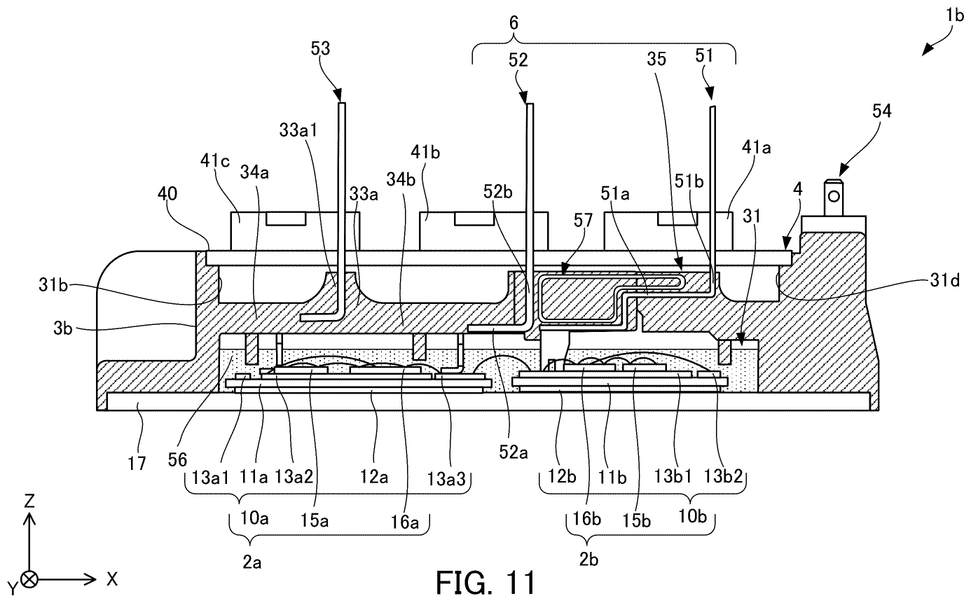

A semiconductor device 1b in practical example 2-2 will be described by the use of FIG. 11. FIG. 11 is a sectional view of a semiconductor device according to the second embodiment (practical example 2-2). FIG. 11 corresponds to FIG. 3 in the first embodiment.

The structure of the semiconductor device 1b in practical example 2-2 is the same as that of the semiconductor device 1 according to the first embodiment except a first lead frame 51 and a conductive member 57. With the first lead frame 51 included in the semiconductor device 1b in practical example 2-2, there is difference in level in a side view on the first horizontal portion 51a of the first lead frame 51 in the first embodiment. The length in the ±X directions of a first horizontal portion 51a of the first lead frame 51 included in the semiconductor device 1b is greater than that of the first horizontal portion 51a of the first lead frame 51 in the first embodiment. The first horizontal portion 51a extends in the +X direction. This is the same with the semiconductor device 1. With the semiconductor device 1b, however, on the way the first horizontal portion 51a extends in the +Z direction by a predetermined height. The first horizontal portion 51a extends again in the +X direction. Accordingly, the distance of a gap G between the first lead frame 51 and a second lead frame 52 in the semiconductor device 1b is longer than that of the gap G in the semiconductor device 1.

As illustrated in FIG. 11, even if the first lead frame 51 is arranged and shaped in this way in the semiconductor device 1b, the conductive member 57 is located in the gap G between the first and second lead frames 51 and 52.

With the conductive member 57 in practical example 2-2, there is also difference in level on the lower portion 57c of the conductive member 57 in the first embodiment (see FIG. 7) corresponding to the difference in level on the first horizontal portion 51a of the first lead frame 51. Furthermore, in practical example 2-2, a side portion 57b of the conductive member 57 is shorter than a side portion 57d of the conductive member 57.

With the conductive member 57 located in the gap G between the first and second lead frames 51 and 52 in practical example 2-2, an outer surface 57d1 of the side portion 57d is adjacent and opposite to a second principal planar surface 52b1 of the second lead frame 52 and an outer surface 57c1 of a lower portion 57c is adjacent and opposite to a third principal planar surface 51a1 of the first horizontal portion 51a of the first lead frame 51. An outer surface 57b1 of the side portion 57b of the conductive member 57 may be adjacent and opposite to a first principal planar surface 51b1 of a first vertical portion 51b of the first lead frame 51.

Accordingly, with the semiconductor device 1b in practical example 2-2, the influence of parasitic inductance is reduced, restrictions on the shape, the arrangement, and wiring routing of the first lead frame 51 and the second lead frame 52 are relaxed, flexibility in design regarding the first lead frame 51 and the second lead frame 52 is improved. This is the same with the first embodiment.

In view of the second embodiment, the conductive member 57 need only include outer surfaces adjacent and opposite to the first and second lead frames 51 and 52. Accordingly, the shape of the conductive member 57 is not limited to a tube. The shape of the conductive member 57 may be a block. However, the weight of the conductive member 57 is reduced by adopting the shape of a tube. As a result, the whole of the semiconductor device 1b becomes lightweight. Furthermore, in the case of the first or the second embodiment, the upper portion 57a of the conductive member 57 is not adjacent or opposite to the first lead frame 51 or the second lead frame 52. Accordingly, the upper portion 57a need only connect the side portions 57b and 57d. The upper portion 57a is not always parallel to the X-Y plane. As long as the upper portion 57a does not prevent a current from flowing through the conductive member 57, it may be, for example, a circular arc (concave or convex) in a side view.

### Third Embodiment

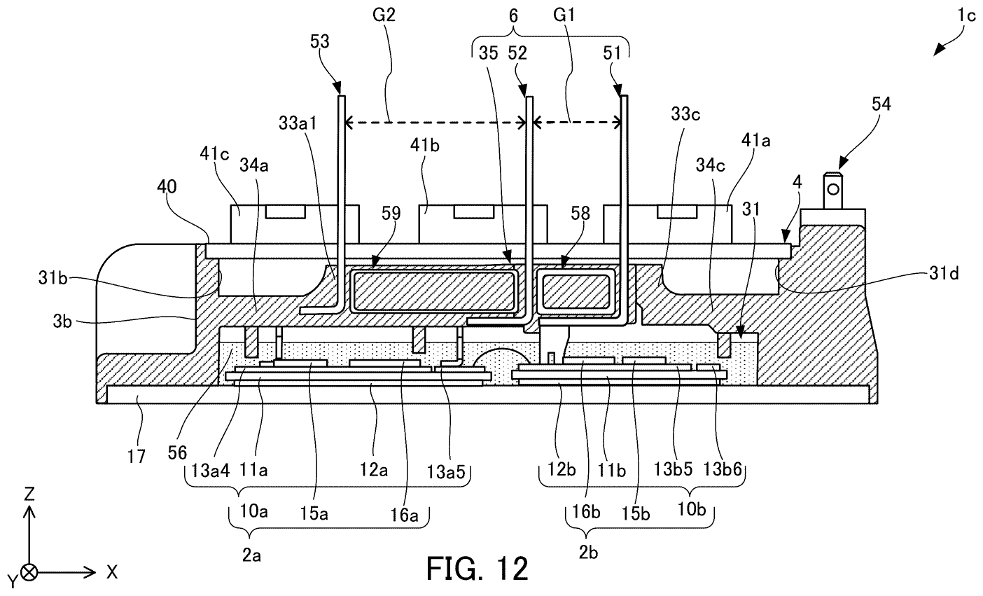

In a third embodiment, a case where a conductive member is located in a gap G between first and second lead frames 51 and 52 and where a conductive member is located in a gap G between second and third lead frames 52 and 53 is taken as an example and will be described by the use of FIG. 12. FIG. 12 is a sectional view of a semiconductor device according to a third embodiment. FIG. 12 corresponds to FIG. 3 in the first embodiment.

A first power supply voltage and a second power supply voltage lower than the first power supply voltage are supplied to the first and third lead frames 51 and 53, respectively, included in a semiconductor device 1c according to a third embodiment. An output voltage is applied to the second lead frame 52 included in the semiconductor device 1c. That is to say, with the semiconductor device 1c, the second lead frame 52 to which an output voltage is applied is located between the first and third lead frames 51 and 53 to which the first and second power supply voltages respectively are supplied.

Furthermore, wiring boards 13a4 and 13a5 and wiring boards 13b5 and 13b6 are formed over insulating plates 11a and 11b included in insulated circuit boards 10a and 10b, respectively, of the semiconductor device 1c. Wiring which enables the above arrangement of the first, second, and third lead frames 51, 52, and 53 is realized by the wiring boards 13a4, 13a5, 13b5, and 13b6. In FIG. 12, wires formed over the insulated circuit boards 10a and 10b are not illustrated. In addition, the second power supply voltage and the first power supply voltage may be supplied to the first and third lead frames 51 and 53 respectively. In this case, wiring which enables this arrangement of the first, second, and third lead frames 51, 52, and 53 is also realized by the wiring boards 13a4 and 13a5 and the wiring boards 13b5 and 13b6 included in the insulated circuit boards 10a and 10b, respectively, of the semiconductor device 1c.

Furthermore, with the semiconductor device 1c, as illustrated in FIG. 12, a conductive member 58 (first conductive member) is located in a gap G1 (first gap) between the first and second lead frames 51 and 52 in the same way as with the conductive member 57 in the first embodiment. Moreover, with the semiconductor device 1c, as illustrated in FIG. 12, a conductive member 59 (second conductive member) is located in a gap G2 (second gap) between the second and third lead frames 52 and 53 in the same way as with the conductive member 57 in the first embodiment. The conductive members 58 and 59 have the shape of a tube. This is the same with the conductive member 57. With the conductive members 58 and 59, a penetration hole is surrounded on all sides by an upper portion, a side portion (third outer surface), a lower portion, and a side portion (fourth outer surface) in order.

With the semiconductor device 1c, the influence of parasitic inductance is also reduced by the conductive members 58 and 59 when the first and second power supply voltages are supplied to the first and third lead frames 51 and 53 respectively. This is the same with the first embodiment. Furthermore, the influence parasitic inductance is reduced by the conductive members 58 and 59 according to a direction in which an output voltage is applied to the second lead frame 52.

Accordingly, with the semiconductor device 1c according to the third embodiment, the influence of parasitic inductance is reduced, restrictions on the shape, the arrangement, and wiring routing of the first, second, and third lead frames 51, 52, and 53 are relaxed, and flexibility in design regarding the first, second, and third lead frames 51, 52, and 53 is improved. This is the same with the first embodiment.

According to the disclosed technique, parasitic inductance is reduced and flexibility in wiring of main terminals is improved.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that various changes, substitutions, and alterations could be made hereto without departing from the spirit and scope of the invention.

What is claimed is:

1. A semiconductor device, comprising:
a first main terminal including a first principal planar surface;
a second main terminal facing the first main terminal with a gap therebetween and including a second principal planar surface located opposite to the first principal planar surface of the first main terminal; and
a conductive member located in the gap and including
a first outer surface adjacent and opposite to the first principal planar surface, and
a second outer surface adjacent and opposite to the second principal planar surface.

2. The semiconductor device according to claim 1, wherein
the first outer surface of the conductive member and the first principal planar surface of the first main terminal have first space therebetween,
the second outer surface of the conductive member and the second principal planar surface of the second main terminal have second space therebetween, and
both the first space and the second space are sealed with a sealing member.

3. The semiconductor device according to claim 1, wherein the first principal planar surface of the first main terminal and the second principal planar surface of the second main terminal are partially opposite to each other.

4. The semiconductor device according to claim 1, wherein the first main terminal further includes:
a first external connection portion at one end portion of the first main terminal; and
a third principal planar surface which is located on another end portion of the first main terminal opposite to said one end portion, and which is perpendicular to the first principal planar surface.

5. The semiconductor device according to claim 4, wherein the conductive member further includes a third outer surface adjacent and opposite to the third principal planar surface.

6. The semiconductor device according to claim 1, wherein the conductive member has a plurality of outer surfaces, including the first outer surface and the second outer surface, to form a shape of a tube to thereby surround a penetration hole, penetration direction of the penetration hole being perpendicular to a direction in which a current flows through the first main terminal.

7. The semiconductor device according to claim 6, wherein:
the first outer surface of the conductive member and the first principal planar surface of the first main terminal has first space therebetween,
the second outer surface of the conductive member and the second principal planar surface of the second main terminal have second space therebetween, and
the first space, the second space, and the penetration hole are sealed with a sealing member.

8. The semiconductor device according to claim 1, wherein the conductive member has a shape of a block and is surrounded by a plurality of outer surfaces including the first outer surface.

9. The semiconductor device according to claim 1, further comprising:
a first semiconductor unit, including:
a first semiconductor chip, having:
a first low potential side electrode on a front surface thereof, and
a first high potential side electrode on a back surface thereof, and
a first insulated circuit board to which the first high potential side electrode of the first semiconductor chip is bonded,
the first main terminal being electrically connected to the first high potential side electrode; and
a second semiconductor unit, including:
a second semiconductor chip, having:
a second low potential side electrode on a front surface thereof, and
a second high potential side electrode on a back surface thereof, and
a second insulated circuit board to which the second high potential side electrode of the second semiconductor chip is bonded,
the second high potential side electrode and the first low potential side electrode being electrically connected, and the second main terminal being electrically connected to the second low potential side electrode.

10. The semiconductor device according to claim 9, wherein the second semiconductor unit further includes a third main terminal electrically connected to the second high potential side electrode of the second semiconductor chip and the first low potential side electrode of the first semiconductor chip.

11. The semiconductor device according to claim 1, wherein:
the first main terminal is configured to receive a first power supply voltage; and
the second main terminal is configured to receive a second power supply voltage different from the first power supply voltage.

12. The semiconductor device according to claim 1, wherein:
the first main terminal is configured to receive a first power supply voltage; and
the second main terminal is configured to receive an output voltage.

13. The semiconductor device according to claim 12, wherein
the conductive member is a first conductive member;
the gap is a first gap;
the second main terminal further includes a third principal planar surface; and
the semiconductor device further includes:
a third main terminal configured to receive a second power supply voltage different from the first power supply voltage, the third main terminal facing the second main terminal with a second gap therebetween, and including a fourth principal planar surface located opposite to the second main terminal, and
a second conductive member located in the second gap, and including:
a third outer surface adjacent and opposite to the third principal planar surface, and
a fourth outer surface adjacent and opposite to the fourth principal planar surface.
